(19) United States
(12) Patent Application Publication
(10) Pub. No.: US 2014/0233339 A1
(43) Pub. Date: Aug. 21, 2014

(54) APPARATUS AND METHOD TO REDUCE BIT LINE DISTURBS

(71) Applicant: SPANSION LLC., Sunnyvale, CA (US)

(72) Inventors: Amichai GIVANT, Rosh Ha'ayin (IL); Ilan BLOOM, Haifa (IL); Mark RANDOLPH, San Jose, CA (US); Zhizheng LIU, San Jose, CA (US)

(73) Assignee: SPANSION LLC., Sunnyvale, CA (US)

(21) Appl. No.: 13/769,403

(22) Filed: Feb. 18, 2013

(51) Int. Cl. G11C 8/08

(52) U.S. Cl. CPC G11C 8/08
USPC 365/230.06

(57) ABSTRACT

A non-volatile memory device comprising a memory cell array including a plurality of non-volatile memory cells arranged in rows and columns, wherein memory cells arranged in a same row share a word line and memory cells arranged in a same column share a bit line; and at least an address decoder to provide a negative voltage to at least one non-accessed word line in said array when a programming or erasure voltage is provided along a shared bit line.

### FIELD OF THE INVENTION

The present invention relates to non-volatile memory arrays generally and to bit line disturbs in non-volatile memory arrays in particular.

### BACKGROUND OF THE INVENTION

Non-volatile memory cells, such as the one shown in FIG. 1, to which reference is now made, comprise a gate G, a source S and a drain D. They are typically organized into non-volatile memory arrays with a large multiplicity of cells 10 arranged in a matrix structure, such as is shown in FIG. 2, to which reference is also made. The gates G of the cells of one row are activated by activating a word line WL and the drains D and sources S of a column of cells 10 are activated by activating two bit lines BL, one for the source S and one for the drain D. In some dense memory arrays, a single bit line connects two adjacent sectors 12.

In addition, the array is divided into sectors 12, where one sector 12 may be activated at a time. Typically, all of the cells 10 of a sector 12 may be erased together, while, for programming, each cell 10 may be individually accessed by its word line and its two bit lines. Typically, sectors 12 lie on top of each other and bit lines BL pass from one sector 12 to the next.

When a cell 10 is activated, its word line is activated as are its two bit lines. 0V (or low positive voltage) is provided to its source bit line and a higher positive voltage is provided to its drain bit line. Its gate is activated by providing voltage to its word line. While it is the only activated cell, the cells between its bit lines all also have power provided to their drains and sources.

In general, the other cells along its column are kept inactive by providing a 0V to the other word lines. This keeps the gates G from affecting the channels 14 which exist between the sources S and drains D of the inactive cells.

As described in U.S. Pat. No. 6,614,692, there may be “disturbs” to the neighboring cells of the activated cell, due to the presence of power on a common word line WL or on common bit lines BL. U.S. Pat. No. 6,614,692 inhibits such disturbs by providing a low positive voltage to the gates of the possibly disturbed cells.

### SUMMARY OF THE PRESENT INVENTION

There is therefore provided, in accordance with a preferred embodiment of the present invention, a non-volatile memory device comprising a memory cell array including a plurality of non-volatile memory cells arranged in rows and columns, wherein memory cells arranged in a same row share a word line and memory cells arranged in a same column share a bit line; and at least an address decoder to provide a negative voltage to at least one non-accessed word line in said array when a programming or erasure voltage is provided along a shared bit line.

There is therefore provided, in accordance with a preferred embodiment of the present invention, a non-volatile memory device comprising a memory cell array comprising a plurality of sectors of non-volatile memory cells which share bit lines, of which one of said sectors is an active sector and the rest are non-active sectors; and at least an address decoder to provide a negative voltage to word lines in said non-active sectors when one of a programming voltage or an erasure voltage is provided along one of said shared bit lines.

There is therefore provided, in accordance with a preferred embodiment of the present invention, a non-volatile memory device comprising a memory cell array including a plurality of non-volatile memory cells arranged in rows and columns, wherein memory cells arranged in a same row share a word line and memory cells arranged in a same column share a bit line; and a bit-line decoder to provide a positive voltage to a source bit line while said one of a programming voltage or erasure voltage is provided to a drain bit line.

There is therefore provided, in accordance with a preferred embodiment of the present invention, a non-volatile memory device comprising a multiplicity of bit lines where source and drain bit lines alternate; and a plurality of two bit, non-volatile memory cells which share bit lines, of which one bit of each cell is a non-data bit located near a source bit line and one bit of each cell is a data bit located near a drain bit line, where said non-data bits are slightly programmed.

According to an embodiment of the present invention, slightly programmed increases the threshold voltage in said memory cells by 0.2V to 1.5V compared to memory cells with two data bits.

There is therefore provided, in accordance with a preferred embodiment of the present invention, a method of reducing bit line disturbs in a non-volatile memory cell in a memory array including a plurality of non-volatile memory cells arranged in rows and columns, wherein memory cells arranged in a same row share a word line and memory cells arranged in a same column share a bit line, comprising providing a negative voltage to non-accessed word lines in said array when a programming or erasure voltage is provided along a shared bit line.

There is therefore provided, in accordance with a preferred embodiment of the present invention, a method of reducing bit line disturbs in non-volatile memory cells in a plurality of sectors of non-volatile memory cells which share bit lines, of which one of said sectors is an active sector and the rest are non-active sectors, comprising providing a negative voltage to word lines in said non-active sectors when one of a programming voltage or an erasure voltage is provided along one of said shared bit lines.

According to an embodiment of the present invention, the method further comprises providing a positive voltage to a source bit line of said shared bit lines while said one of a programming voltage or erasure voltage is provided.

According to an embodiment of the present invention, the negative voltage is in a range from −0.1V to −3V.

According to an embodiment of the present invention, the negative voltage is in a range from −0.1V to −2.5V.

According to an embodiment of the present invention, the negative voltage is in a range from −0.2V to −2 V.

According to an embodiment of the present invention, the positive voltage is in a range from 0.01V to 2V.

According to an embodiment of the present invention, the positive voltage is in a range from 0.01V to 1.5V.

According to an embodiment of the present invention, the positive voltage is in a range from 0.05V to 1V.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 schematically illustrates an exemplary non-volatile memory cell;

FIG. 2 schematically illustrates an exemplary non-volatile memory cell array arranged in a matrix structure;

FIGS. 3A and 3B schematically illustrate exemplary non-volatile memory cells at programmed and erased states, and the resulting hole and electron injection due to Bit-line disturb conditions;

FIG. 4 schematically illustrates an active sector with a programming voltage applied to a word line in the sector, and a non-active sector with a negative voltage applied to all word lines in the sector, according to an embodiment of the present invention;

FIG. 5 shows graphs of the results of an accelerated life BLD stress test conducted by the Applicants on a programmed memory cell and an erased memory cell, according to an embodiment of the present invention;

FIG. 6 is shows graphs of changes in threshold voltage Vt over lifetime of a NVM device for different source and gate voltages as measured during an accelerated life BLD stress test simulating normal conditions, according to an embodiment of the present invention;

FIG. 7 schematically illustrates an exemplary two-bit memory cell;

FIG. 8 schematically illustrates exemplary memory array architecture for accessing only one of two bit cells to provide reduced bit line disturbs due to DIBL, according to an embodiment of the present invention;

FIG. 9 shows graphs for an array architecture similar to that shown in FIG. 8, of the impact of partial programming of a complementary bit (non-data bit) on bit line disturbs for programmed and erased normal (data) bit over lifetime of a NVM device as measured during an accelerated life BLD stress test, according to an embodiment of the present invention; and

FIG. 10 schematically illustrates an exemplary non-volatile memory device

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE PRESENT INVENTION

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

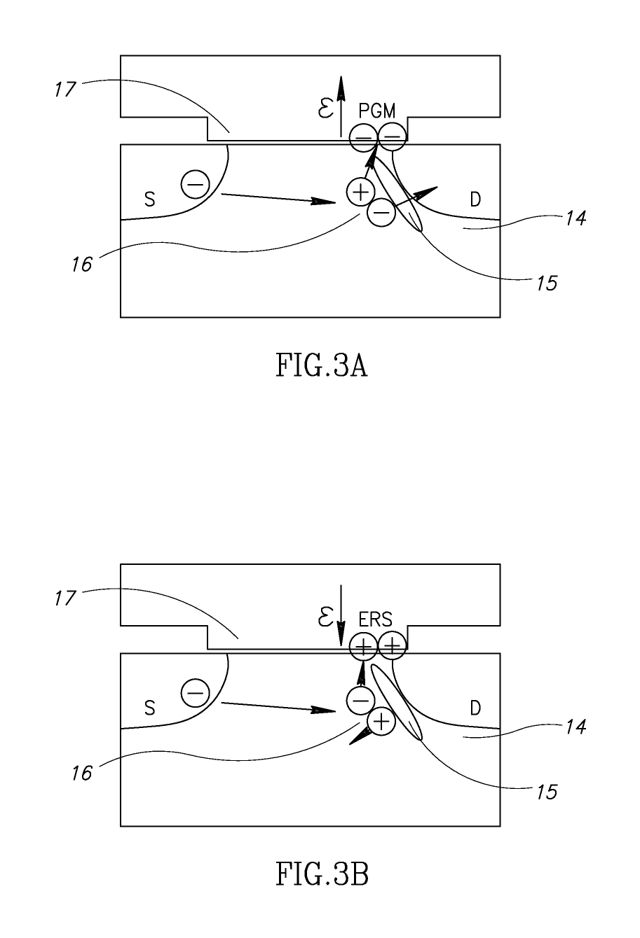

Applicants have realized that, as cells are continually reduced in size the bit lines BL of FIG. 2 become closer together and previously ignorable effects become significant. There is a leakage effect, known as “drain induced barrier lowering” (DIBL), which occurs across short channels 14 when the gate is closed and a voltage drop exists between the drain and source of a cell. As shown in FIGS. 3A and 3B, to which reference is now made, the resulting electric field 15 near the drain D will pull electrons from the source S (i.e. they will penetrate through channel 14 to the drain), even if the gate is inactive. DIBL happens when the source and drain are close together.

When the electrons arrive at the drain, they are accelerated in the channel by the high electric field 15 around the drain junction (i.e. the intersection between the p-type drain and the n-type substrate in channel 14) and they collide with the channel lattice atoms near the drain, such as an atom 16. The collision may induce ionization of an electron from atom 16 and formation of an electron—hole pair. Such process is also referred as “Impact Ionization” (II).

As shown in FIG. 3A, the presence of charge in a charge storage area 17 between gate G and channel 14 may provide a vertical field upward towards charge storage area 17 for positive holes, which are attracted to the negative charge stored in charge storage area 17, in a process known as “secondary injection”.

Alternatively and as shown in FIG. 3B, for an erased bit, the presence of positive holes in charge storage area 17 may provide a vertical field upward towards charge storage area 17 for negatively charged electrons, which are attracted to the positive holes in charge storage area 17.

Unfortunately, charge storage area 17 is not supposed to receive any change of charge (whether an additional hole, which reduces the amount of charge, or an additional electron, which raises the amount of charge) since the cell was not activated (recall that its gate G was not activated). Therefore, the change in charge level is known as a “disturb” and this type of disturb, which comes from the activation of the bit lines, is known as a “bit line disturb”.

Applicants have realized that bit line disturbs are particularly bothersome for sectors 12 (FIG. 2) which are not currently activated. If a sector is not activated, nothing should happen to its cells. Yet, because, as shown in FIG. 2, the bit lines BL are shared among sectors 12, power is provided along bit lines BL of non-activated sectors as well as of the activated sector. As a result, the cells along the column between the powered bit lines can have bit line disturbs and thus, the amount of charge in their cells may change.

Applicants have further realized that providing positive power to the word lines of the inactive sector(s), exacerbates the bit line disturbs of the inactive sectors since, as Applicants have realized, the bit line disturbs are caused by DIBL and the resultant channel penetration and secondary injection is increased with power on the gate of a cell.

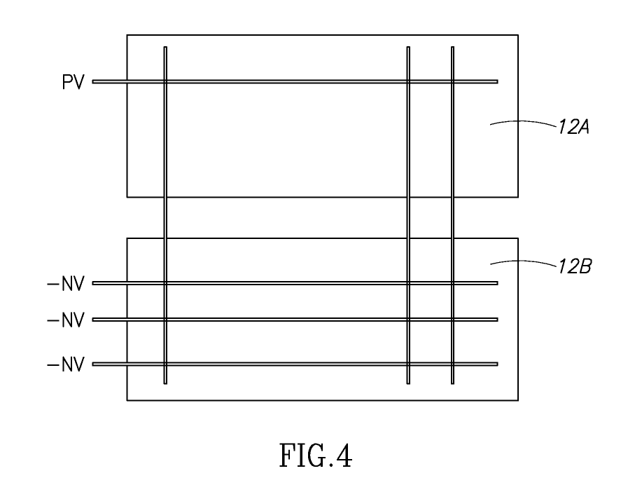

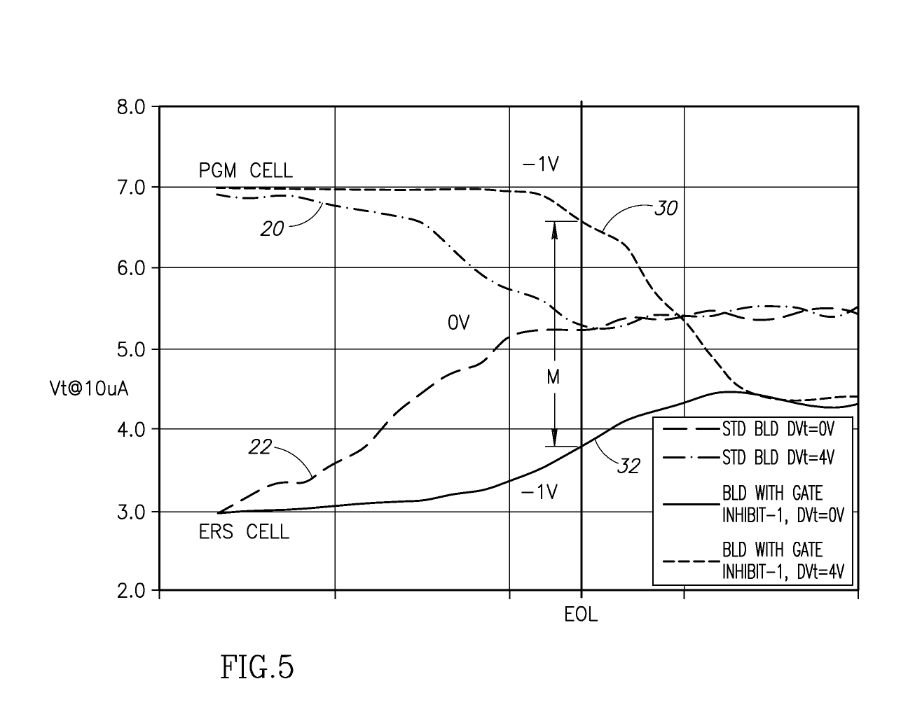

In accordance with a preferred embodiment of the present invention and as shown in FIG. 4 to which reference is now made, a negative voltage -NV may be provided to the word lines of the inactive sector(s) that are affected by bit line disturbs. In FIG. 4, sector 12A may be the activated sector, with a programming voltage PV on the word line accessing the activated cell. Sector 12B may represent the inactive sector(s) in which negative voltage −NV may be applied to all of its word lines (FIG. 4 shows only three word lines for clarity only; a typical sector may have many more).

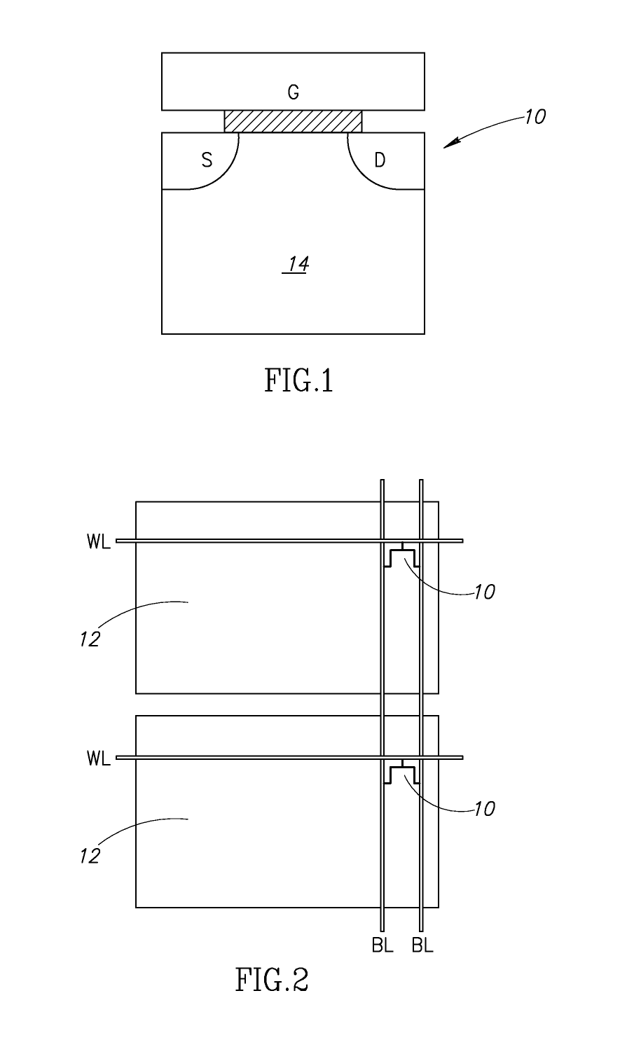

It will be appreciated that negative gate voltage −NV may inhibit DIBL by increasing the potential barrier of the channel 14 (FIG. 1). As a result, the probability of electrons to penetrate through the channel is significantly reduced than when the gate voltage is 0V. It will further be appreciated that negative voltage −NV may be relatively small compared to an erase gate voltage and may be in a range from −3 to −0.1V; for example, −NV may be −2V, −1V, −0.8V, −0.5V, −0.3V, −0.2V.

Applicants have also realized that the negative gate voltage −NV may also be applied to unselected word lines in active sector 12A to reduce possible effect of BLD in cells connected to the unselected word lines. It may be appreciated that the BLD effect on these active sector cells (cells connected to unselected word lines in active sector 12A) is substantially less compared to the cells in non-active sector 12B as the cumulative disturb time on the active sector cells is equal to that of one erase cycle.

Applicants have further realized that BLD may occur during erase operations where the source is not floating, and that the effect of BLD may be substantially reduced by applying the negative voltage −NV to the word lines on non-active sector 12B.

FIG. 5, to which reference is now briefly made, shows the changing threshold voltage of a programmed cell (graph 20) and of an erased cell (graph 22) during an accelerated life BLD stress test conducted by the Applicants, according to an embodiment of the present invention. The accelerated life test simulated a worst case operating scenario of BLD stress in cells in a non-active sector with 0V on the gates, after pre-conditioning of 10,000 program/erase cycles. This worst case scenario assumes that a same victimizing sector (e.g. the same active sector) is exposed to all the cycling typically encountered by a NVM device during its lifetime (i.e. end of life, EOL=100,000 cycles) and always induces BLD in a same victim sector (e.g. the same inactive sector) during the lifetime. The x-axis is logarithmic-based and is representative of the lifetime of the memory device. As can be seen, the margin between the programmed state and the erased state is reduced over the lifetime, such that, it is no longer possible to distinguish between the two states approximately at a point of intersection of the two graphs substantially coinciding with a point on a vertical EOL line representing the end-of-life (EOL) of the cell. This lack of margin means that the cell is no longer functional at EOL, and it occurs approximately after 100,000 cycles.

FIG. 5 also compares the results for a cell in a non-active sector with a negative voltage of −1V on its gate. Graph 30 shows the changing threshold voltage Vt (the threshold at which the cell begins to pass current) of a programmed cell and graph 32 shows the changing threshold voltage Vt of an erased cell. These graphs stay stable for much longer, leaving a significant margin M at the end of life (EOL) line. Thus, by slightly reducing the word line voltage of a non-active sector during programming of a cell in an active sector, the bit line disturb of the non-active sector is significantly reduced.

Applicants have realized that BLD may be substantially reduced by applying a positive biasing voltage to the common source bitline of active and non-active sectors, during programming operation of the active sector. Applying the positive biasing voltage to the source bit line increases the source-channel potential barrier which may reduce the probability of electrons penetrating through the channel. The positive biasing voltage may be in a range of 0.01V to 2V, for example, 0.02V, 0.05V, 0.08V, 0.15V, 0.3V, 0.5V, 0.7V, 0.8V, 0.9V, 1V, 1.5V, 1.8V. This positive biasing voltage may also be applied to the source bit line together with −NV to the word lines in the non-active sector and/or the unselected word lines in the active sector when applying the programming voltage PV to selected word line in the active sector to reduce BLD.

Applicants have additionally realized that DIBL may also be inhibited by increasing the source voltage while keeping a similar voltage drop across channel 14 from source S to drain D, known as Vds. Thus, if the voltage on source S is increased by 1V, the voltage on drain D may be increased by 1V. Under such conditions the programming efficiency is not impaired

Applicants have further realized that BLD may occur during erase operations where the source is not floating, and that the effect of BLD may be substantially reduced by applying a positive biasing voltage to the source bit line. This positive biasing voltage may also be applied to the source bit line together with −NV to the word lines in the non-active sector.

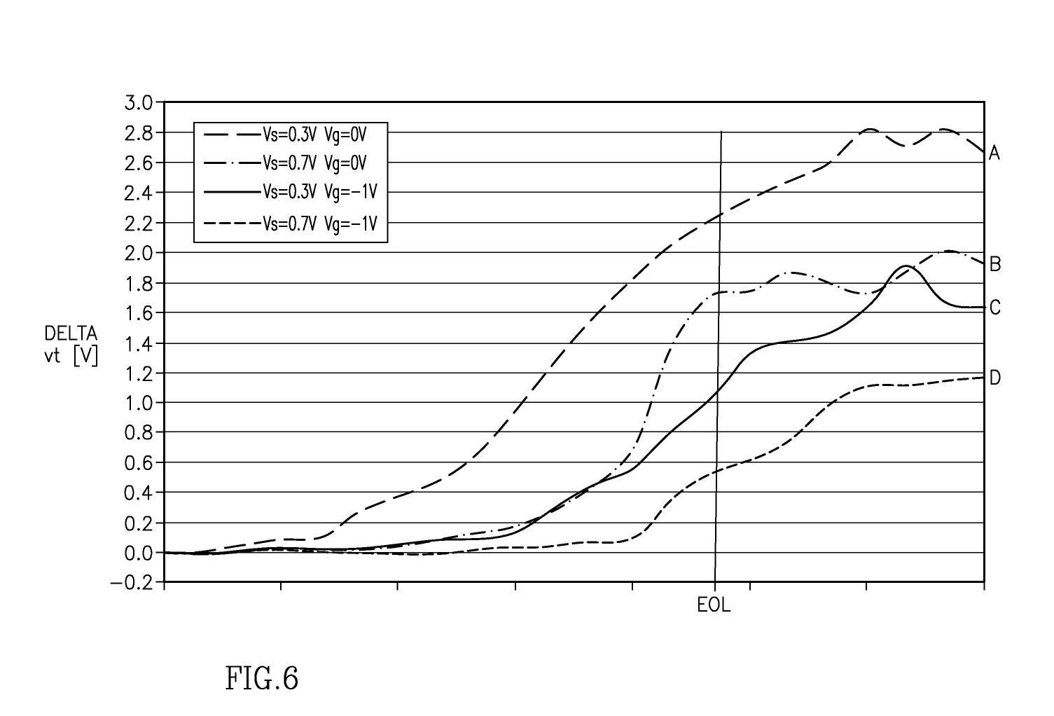

FIG. 6, to which reference is now made, shows the change in erased cell threshold voltage Vt plotted on a logarithmic-based x-axis representing the lifetime of the NVM device, for different positive source biasing voltages and gate voltages, as measured during a life BLD stress test simulating the worst case operating scenario, according to an embodiment of the present invention. For each graph, the voltage drop Vds is kept at 4V. In graphs (A) and (B), the gate voltage is 0V and in graphs (C) and (D) the gate voltage is −1V. In graphs (A) and (C), the source voltage is 0.3V while those of graphs (B) and (D) are 0.7V. As can be seen, the change in threshold voltage Vt increases if the source voltage is slightly positive while the gate voltage is kept at 0V (i.e. graph (A) provides the most increase). The EOL is indicated by the vertical EOL line, the point of intersection of each graph with the EOL line representing the measured change in threshold voltage Vt at EOL. As may be appreciated from the graphs, applying a positive biasing voltage to the source helps mitigate BDL.

Applicants have also realized that DIBL can be reduced if there is charge over source S since, as is known in the art, the presence of negative charge above the channel inhibits the flow of current from source to drain for a given gate voltage. This is the definition of the threshold voltage—it is the voltage at which current begins to flow. As Applicants have realized, the presence of negative charge near source S will inhibit the flow of current out of source S until a higher threshold voltage is applied and thus, will also inhibit the ability of the cell to create a DIBL current.

This is particularly important for some charge-trapping non-volatile memory cells which store two bits of charge, in two separate charge storage areas, one near source S and one near drain D.

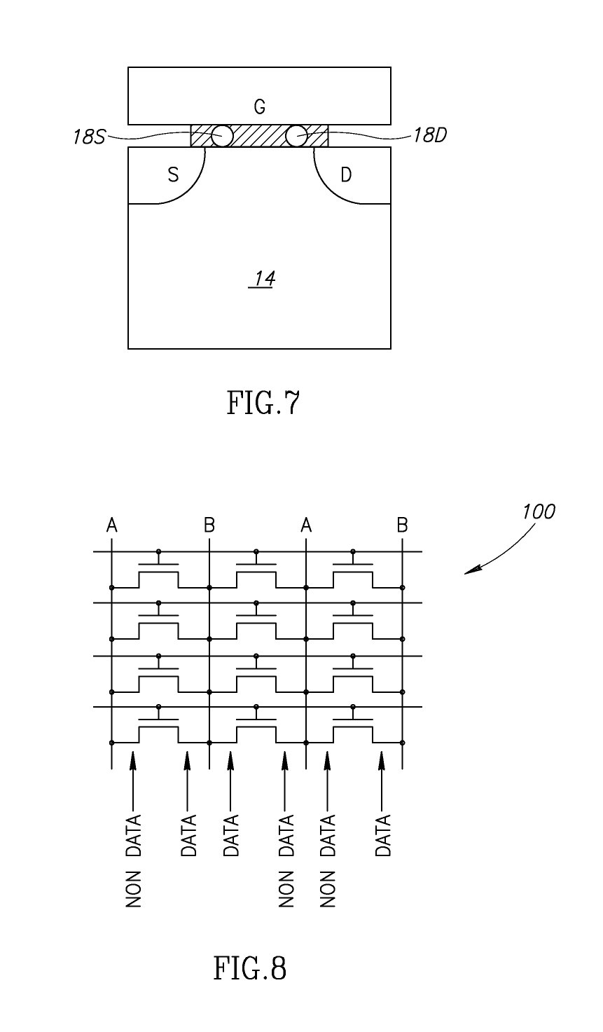

An example of such a cell is shown in FIG. 7, to which reference is now made. In this cell, there are two charge storage areas, one, 18S, near source S and one, 18D, near drain D. If charge storage area 18S, near source S, is programmed (i.e. there are electrons in charge storage area 18S), it is harder for an electron from source S to escape towards drain D since the electrons in charge storage area 18S increase the potential barrier between channel and source (this is the barrier for electrons in the source side).

Applicants have realized that the DIBL current and thus the bit line disturbs may be inhibited by keeping charge storage area 18S over the source bit line (whichever bit line is so defined) permanently charged. This may reduce the number of bits available for programming (from 2 bits per cell to 1 bit per cell) but it may make those bits which are available more reliable, for a longer period of time.

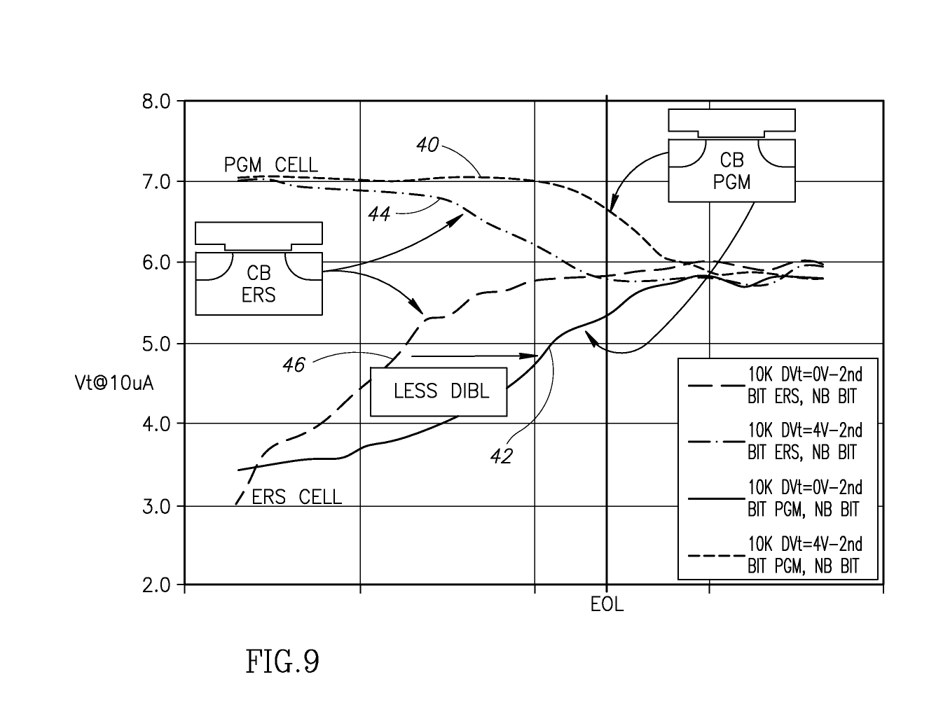

FIG. 8, to which reference is now made, is an array architecture 100 for accessing only one of the two bit cells, which may provide reduced bit line disturbs due to DIBL. Array 100 may be similar to the array of FIG. 2, in which there is a column of non-volatile memory cells between every two neighboring bit lines, except that in array 100, the bit lines are divided into two groups, the A group and the B group, and bit lines from these two groups alternate. Thus, as can be seen in FIG. 9, the bit lines are labeled A, B, A, B, etc. Thus, each memory cell has one A bit line and one B bit line.

In accordance with a preferred embodiment of the present invention, each cell has a data bit and a non-data bit and the non-data bits are those near the A bit lines. The data bits are those near the B bit lines. Thus, each B bit line has a data bit on either side of it and each A bit line has a non-data bit on either side of it. The A bit lines may act as sources S for all of the cells while the B bit lines may act as drains for them all.

In accordance with a preferred embodiment of the present invention, all of the non-data bits are slightly programmed initially following production and are never programmed nor erased during the operating life of the array. Moreover, the elements powering the bit lines may ensure that the bit lines associated with the non-data bits, i.e. the A bit lines, do not receive voltages exceeding a read/verify voltage level. This may ensure that the sources S never approach programming or erase voltages and thus, the amount of charge in charge storage area 18S should never change. The result is that a significant potential barrier remains near the sources S at all times, inhibiting the DIBL current in all non-activated cells, both in the active sector and in the inactive sectors.

FIG. 9, to which reference is now made, shows graphs, for an array having a similar architecture to that of FIG. 8, of the bit line disturbs for all possible states of cells plotted on a logarithmic-based x-axis representing the lifetime of the NVM device, as measured during an accelerated life BLD stress test simulating a worst case operating scenario, according to an embodiment of the present invention. In graphs 40 and 42, charge storage area 18S is programmed (the non-data bit or complementary bit, CB, stored therein is programmed), while in graphs 44 and 46, charge storage area 18S is erased (CB is erased). In graphs 40 and 44, the data bit is erased while in graphs 42 and 46 the data bit is programmed. The EOL is indicated by the vertical EOL line, the point of intersection of each graph with the EOL line representing the measured threshold voltage Vt at EOL.

As can be seen, graphs 40 and 42 (with charge storage area 18S programmed) converge one order of magnitude (10×) slower compared to graphs 44 and 46 (with charge storage area 18S erased). Thus, keeping charge storage area 18S programmed increases the lifetime of the array, leaving a significant margin between the programmed and erased states of the data bit at the end of life.

It will be appreciated that charge storage area 18S does not need to be programmed to a very high level. A small amount of charge, such as may provide an increase in threshold voltage of between 0.2V-1.5V, for example, 0.2, 0.3, 0.4V, 0.5V, 0.7V, 0.9V, 1V, 1.2V, 1.3V, 1.4V, 1.5V.

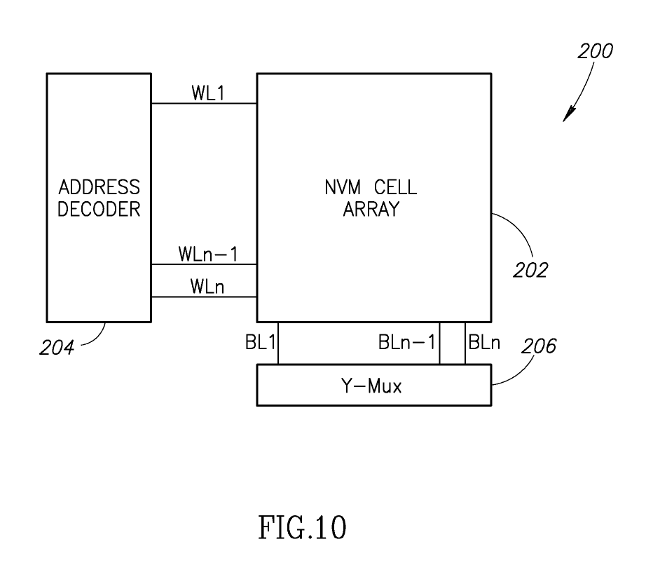

It will be appreciated that an exemplary memory device 200 according to the present invention and shown in FIG. 10 may include circuitry to implement in a non-volatile memory (NVM) cell array 202 the voltage levels discussed herein. Thus, a bit line decoder, such as a Y-MUX, 206 may provide higher source voltages, as discussed hereinabove with respect to one embodiment, while an address decoder 204 may provide the slightly negative voltage to the word lines, as discussed hereinabove with respect to another embodiment. It will be appreciated that NVM cell array 202 may include a plurality of sectors which may share bit lines (see FIG. 2). Alternatively, NVM cell array 202 may not be distributed into sectors and may include the cells arranged into an array of rows and columns, with the cells in a same row sharing a word line and the cells in a same column sharing a source bit line and a drain bit line. It may be additionally appreciated that the sectors may include memory cells adapted to store one bit, or alternatively store more than one bit.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A non-volatile memory device comprising:
a memory cell array including a plurality of non-volatile memory cells arranged in rows and columns, wherein memory cells arranged in a same row share a word line and memory cells arranged in a same column share a bit line; and
at least an address decoder to provide a negative voltage to at least one non-accessed word line in said array when a programming or erasure voltage is provided along a shared bit line.

2. The non-volatile memory device according to claim 1 and wherein said negative voltage is in a range from −0.1V to −3V.

3. The non-volatile memory device according to claim 1 and wherein said negative voltage is in a range from −0.1V to −2.5V.

4. The non-volatile memory device according to claim 1 and wherein said negative voltage is in a range from −0.2V to −2 V.

5. A non-volatile memory device comprising:
a memory cell array comprising a plurality of sectors of non-volatile memory cells which share bit lines, of which one of said sectors is an active sector and the rest are non-active sectors; and
at least an address decoder to provide a negative voltage to word lines in said non-active sectors when one of a programming voltage or an erasure voltage is provided along one of said shared bit lines.

6. The non-volatile memory device according to claim 5 and wherein said negative voltage is in a range from −0.1V to −3V.

7. A non-volatile memory device comprising:
a memory cell array including a plurality of non-volatile memory cells arranged in rows and columns, wherein memory cells arranged in a same row share a word line and memory cells arranged in a same column share a bit line; and
a bit-line decoder to provide a positive voltage to a source bit line while said one of a programming voltage or erasure voltage is provided to a drain bit line.

8. The non-volatile memory device according to claim 7 and wherein said positive voltage is in a range from 0.01V to 2V.

9. The non-volatile memory device according to claim 7 and wherein said positive voltage is in a range from 0.01V to 1.5V.

10. The non-volatile memory device according to claim 7 and wherein said positive voltage is in a range from 0.05V to 1V.

11. A non-volatile memory device comprising:
a multiplicity of bit lines where source and drain bit lines alternate; and
a plurality of two bit, non-volatile memory cells which share bit lines, of which one bit of each cell is a non-data bit located near a source bit line and one bit of each cell is a data bit located near a drain bit line, where said non-data bits are slightly programmed

12. The non-volatile memory device according to claim 11 and wherein slightly programmed increases the threshold voltage in said memory cells by 0.2V to 1.5V compared to memory cells with two data bits.

13. A method of reducing bit line disturbs in non-volatile memory cell in a memory array including a plurality of non-volatile memory cells arranged in rows and columns, wherein memory cells arranged in a same row share a word line and memory cells arranged in a same column share a bit line, comprising providing a negative voltage to non-accessed word lines in said array when a programming or erasure voltage is provided along a shared bit line

14. The method according to claim 13 and wherein said negative voltage is in a range from −0.1V to −3V.

15. A method of reducing bit line disturbs in non-volatile memory cells in a plurality of sectors of non-volatile memory cells which share bit lines, of which one of said sectors is an active sector and the rest are non-active sectors, comprising providing a negative voltage to word lines in said non-active sectors when one of a programming voltage or an erasure voltage is provided along one of said shared bit lines.

16. The method according to claim 15 and wherein said negative voltage is in a range from −0.1V to −3V.

17. The method according to claim 15 and further comprising providing a positive voltage to a source bit line of said shared bit lines while said one of a programming voltage or erasure voltage is provided.

18. The method according to claim 17 and wherein said positive voltage is in a range from 0.05V to 1V.
